(19) United States
(12) Patent Application Publication
(10) Pub. No.: US 2007/0215376 A1
(43) Pub. Date: Sep. 20, 2007

(54) Method For Printing Electrical And/Or Electronic Structures And Film For Use In Such A Method

(75) Inventor: Thomas Walther, Hofheim (DE)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: MAN ROLAND DRUCKMASCHINEN AG, Offenbach (DE)

(21) Appl. No.: 11/578,912

(22) PCT Filed: Apr. 16, 2005
(86) PCT No.: PCT/EP05/04061

§ 371 Date: Jan. 3, 2007

(30) Foreign Application Priority Data
Apr. 19, 2004 (DE) 10 2004 019 412.2

(51) Int. Cl. H05K 3/12; H05K 1/00

(52) U.S. Cl. 174/250; 29/846

(57) ABSTRACT

The invention relates to a method for printing electrical and/or electronic structures, especially electrical conductors and/or electronic circuits onto a printing material, whereby the printing material is transported through a plurality of printing units of a printing machine that are disposed one after the other. A design of the electrical and/or electronic structure to be printed is applied to the printing material in one or more first printing units by means of an adhesive. The printing material, which is partially imprinted with the adhesive is then fed to one or more second printing units in which a conductive material is applied to the areas of the printing material that are imprinted with the adhesive.

### FIELD OF THE INVENTION

The invention concerns a method for printing electrical and/or electronic structures, in particular electrical conductors and/or electronic circuits.

### BACKGROUND OF THE INVENTION

There are various well-known methods for transferring electrical and/or electronic circuit components or the entire circuit to a carrier substrate and/or a material to be printed by printing methods such as offset printing. Because very small elements can be represented in offset printing, offset printing is generally preferred for manufacturing components or a complete electronic circuit. This is widely known from lithographic methods for circuit production.

In relation to other printing methods, such as ink jet printing, offset printing also has the fundamental advantage that a comparatively high productivity can be achieved with the permanent printing plate of offset printing, and very high degrees of structural fineness can be achieved by optimizing the imaging process. The essential advantage of offset printing, however, is that the package of an electronic component, such as an RFID-label, can be manufactured in one work step. The components of an RFID label can be printed directly on the package in the first printing units of an offset printing machine, and the remainder of the package can be finished in the remaining printing units.

In principle, offset printing can utilize three different application methods: wet offset printing, waterless offset printing, also referred to as the Toray method, and dry offset printing, also referred to as the letterset method. In strict terms, the letterset method is a relief printing method, since a letterpress plate is clamped instead of a lithographic printing plate. All methods share the characteristic that the printed image is transferred from the printing plate (photolithography plate) to the printing material via a rubber blanket as an intermediate member.

Unlike with classic printed materials, the critical point when electronic circuits are printed is not a good visual rendition, but rather the satisfaction of electrical and physical requirements. Thus, for instance, the resistance of a conductor depends not only on the material properties of the conductive material that has been applied, but also on the geometry of the cross section of a line. The thinnest point of the conductor defines the effective electrical resistance. A reproducible, defined electrical function thus demands an optimally even, homogeneous application of the conductive printing ink.

If one considers the different methods of offset printing, they all have weaknesses, either in the attainable resolution or in the insufficient homogeneity of the application of conductive ink. In wet offset printing, a problem is that part of the moistening agent is emulsified into the offset ink and is present to a certain extent as free surface water. If this printing ink/moistening agent emulsion is transferred to the material to be printed, an inhomogeneous distribution of the moistening agent results which can lead to ink transfer irregularities. This can lead to defects in the conductors, and in conjunction therewith, changes of the electric/physical properties.

In comparison to wet offset printing, the waterless offset printing method (Toray method) offers a more cohesive print surface, and therefore can be better suited to the application of electrical conductors. A disadvantage with this method, however, is that the ink must contain a certain amount of silicone oil for the separation between image and non-image sections. This silicone oil is a very good insulator, and therefore can impair the conductivity of the conductors in an unpredictable manner.

The dry offset method with letterset plates has the advantage that higher layer thicknesses can be transferred than in wet offset printing, but the relatively low resolution of the image elements with letterset plates is a disadvantage. Nevertheless, indirect printing with dry offset printing plates is a suitable method, at least with simple circuit designs, for transferring conductive structures indirectly, via the intermediate rubber blanket, to a material to be printed.

Another disadvantage of the offset printing method for the application of conductors is that the relatively thin layers that can be applied with offset printing (maximum of 3 μm) are often only marginally acceptable for layers of the required type. This produces a relatively high volume resistance. In addition, the quality of the layers is highly susceptible to technical defects in printing. The absorption of the printing ink into the printing material can also lead to changes in the electrical/physical characteristics.

While the printing of conductive structures with appropriately modified sheet-fed offset inks having conductive components is possible, the conductivity is hampered by the fact that pigments or conductive structures are bound in a vehicle. In the production of sheet-fed offset inks, the pigments and the vehicle are ground until the individual pigments are wetted as optimally as possible with the vehicle. The pigments and vehicle have no or hardly any direct contact with one another. As a result, metallic pigments that are ground up in an unmodified vehicle do not necessarily produce a properly conductive structure.

### BACKGROUND AND SUMMARY OF THE INVENTION

In view of the foregoing, an object of the present invention is to create a new method for printing electrical and/or electronic structures, in particular electrical conductors and/or electronic circuits.

According to the invention, in one or more first printing units, a design of the electrical and/or electronic structure to be printed is applied with an adhesive onto a printing material. The printing material partially printed with the adhesive, is then fed to one or more second printing units, in which an electrically conductive material is applied to the areas of the material to be printed that are imprinted with the adhesive.

The present invention also provides a film for use in a method for printing electrical and/or electronic structures, in particular electrical conductors and/or electronic circuits.

Embodiments of the invention, without it being limited thereto, will be described in greater detail below on the basis of the drawings.

### BRIEF DESCRIPTION OF THE DRAWING

FIG. 1 is a schematic cross-sectional view of a portion of an illustrative printing machine showing how the method of the present invention can be used to print electrical and/or electronic structures, in particular electrical conductors and/or electronic circuits.

### DETAILED DESCRIPTION OF THE INVENTION

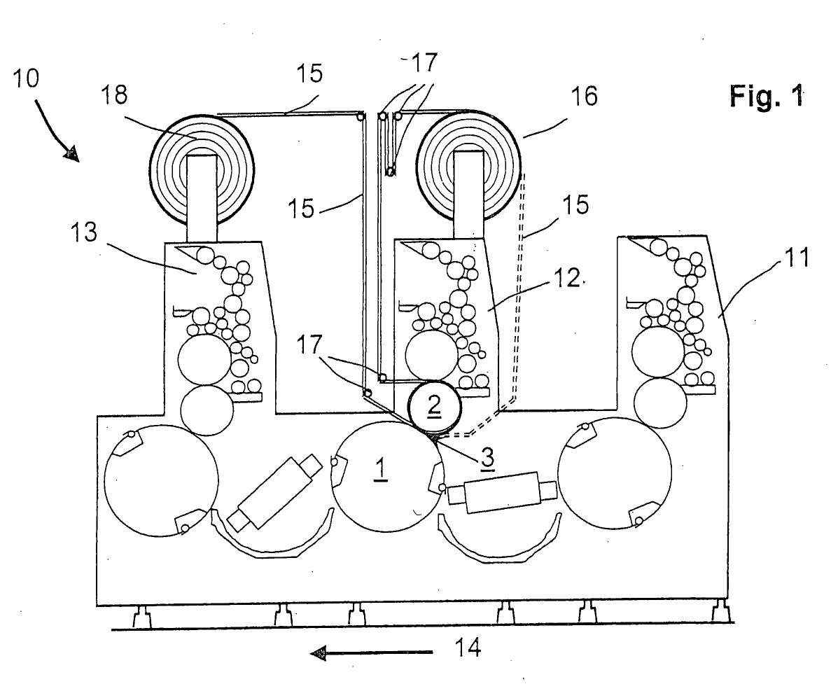

FIG. 1 shows a section of a printing machine 10 including three printing units 11, 12 and 13 arranged one after another. A material to be printed (i.e., printing material) is moved in the direction of arrow 14 through printing units 11, 12 and 13. As described below, an electronic and/or electrical structure can be applied to the printing material using the method according to the present invention.

With the present invention, a design of the electrical and/or electronic structure to be printed can be applied with an adhesive to the printing material in one or more first printing units, represented by printing unit 11 in the embodiment of FIG. 1. The material to be printed, which has been partially imprinted with adhesive, is then fed to a second printing unit, represented by printing unit 12 in the embodiment of FIG. 1. In the second printing unit 12, a conductive material is applied to the areas of the material to be printed that were imprinted with adhesive in the first printing unit 11. The adhesive is preferably applied by offset printing in the first printing unit 11. In this case, the first printing unit 11 is constructed as an offset printing unit. Alternatively, it is also possible for the first printing unit 11 to be embodied as a direct or indirect letterpress printing unit, for applying the adhesive by direct or indirect letterset printing to the material to be printed.

In a particularly preferred embodiment of the present invention, the printing material that has been partially imprinted with adhesive is applied to a film 15 in the second printing unit 12, as shown in FIG. 1. The film 15 carries a removable layer of an electrically conductive and/or semiconductive material, which is transferred from the film 15 to the areas of the printing material that have been imprinted with adhesive. As shown in FIG. 1, the film 15 can be unwound from a first drum and/or supply reel 16 and fed to the second printing unit 12 via, if desired, several deflection rollers 17. The deflection rollers 17 can contain so-called dancer rolls for maintaining a sufficient web tension of the film 15.

The second printing unit 12 has at least one impression cylinder 1 and a press roller 2. The press roller 2 preferably corresponds to the blanket cylinder of an offset printing unit or the form cylinder of a varnishing module. The film 15 is led around the press roller 2 either in the manner shown in FIG. 1, or approximately tangentially past the press roller 2, through a transfer gap 3 between the press roller 2 and the impression cylinder 1. Here the film 15 is placed with its coated side against the material to be printed and together they are led under pressure through the transfer gap 3. The coating and/or conductive material of the film 15 is transferred in the area of the adhesive design onto the printing material.

After transfer of the conductive material to the areas of the printing material that are imprinted with adhesive, the film 15 is wound up on a drum and/or a winding reel 18. Thus, a film completely or fully covered with conductive material is present on the supply reel 16, while parts of the conductive material on the winding reel 18 have been transferred from the film 15 to the printing material. The film wound on the winding reel 18 is therefore a used film with an incomplete layer of conductive and/or semiconductive material. If the film 15 is coated, for example, with an aluminum layer or some other type of conductive material layer, parts of this layer have been removed by transfer in the transfer gap 3 to the printing material. The rest of the coating remains on the film 15.

The present invention also encompasses recoating the used film 15 with conductive material following transfer of the conductive material to the areas of the printing material that are imprinted with adhesive. This can be done, for example, via electrostatic coating, sputtering, powder-coating or spraying. A circulating endless film that is coated repeatedly with conductive substance by, for instance, a doctor blade system or by electrostatic coating is another conceivable way to perform the coating. This could be done, for instance, by sprinkling an electrically charged film over and over again with oppositely-charged conductive carbon blacks and removing excess material by vibration, with a doctor blade, a brush, or some other type of device.

It is also possible to apply the conductive substance in liquid form for renewing the coating of the consumed film. In such a case, the application can be performed by an ink chamber blade system, a spraying device or a roll mill. Surplus coating is removed after coating by a doctor blade system, an air knife or a roller system. Once a homogeneous film of the coating is present on the belt or the cylinder, the coating is dried by a drying unit with the goal of obtaining as solvent-free a coating as possible which is not contaminated by nonconductive substances. It is also possible to produce a defined layer thickness of a conductive substance on a film without a subsequent drying process by transferring the conductive substance to the printing material by laser pulses.

Following application of the conductive material to the areas of the printing material that are imprinted with adhesive, the printing material can be fed to a third printing unit 13. The third printing unit 13 can execute further processing such that the layer thickness of the transferred conductive material is adjusted to a defined dimension. This can be done, for example, with a doctor blade mechanism having a positive or negative blade position, a calendering unit or an air knife. The printing material that is coated with electrically conductive material can also be subjected to a pressing or smoothing operation in the third printing unit 13. The layer thickness of the conductive material can be adjusted to a defined dimension using such operations as well.

In contrast to the embodiment of FIG. 1, the electrically conductive material can also be applied to the areas of the printing material that are imprinted with adhesive using a cylinder instead of a film 15. For example printing material can be fed in the second printing unit 12 to a cylinder that transfers a conductive material to the areas of the printing material that are imprinted with adhesive. This cylinder can be the press roller 2. Similarly, a charged cylinder which is sprinkled repeatedly with an oppositely-charged electrically conductive or semiconductive substance could be used. This substance is transferred only in the areas of the printing material in which the adhesive has been applied to the printing material.

In connection with the embodiment of the invention shown in FIG. 1, a film 15 is used for transferring the conductive material to the areas of the printing material that are imprinted with adhesive. The film 15 has at least a two-ply and/or two-layered structure consisting of a carrier film and an electrically conductive functional layer. The electrically conductive functional layer can be applied directly to the carrier film. Preferably, however, an embodiment of film 15 with a three-layered or three-ply structure is used. In such a three-layered or three-ply structure, a separation layer or adhesion-promoting layer is positioned between the carrier film and the electrically conductive functional layer.

The carrier film and/or the separation layer is formed as a low-energy film or layer with a surface energy of preferably less than 35 mNm, so that a low adhesion is imparted to the electrically conductive functional layer. The electrically conductive functional layer thus easily detaches from the carrier film and/or the separation layer and consequently can be transferred with relatively little power or pressure to the areas of the printing material that are coated with adhesive.

The electrically conductive functional layer can be connected to the carrier film preferably by lamination via the intermediate separation layer. Alternatively, it is possible for the electrically conductive functional layer to be directly connected to the carrier film by adhesion or by electrical charge forces or electrostatic adhesion.

The electrically conductive functional layer is preferably formed as a predominantly metallic layer. It can be formed, for example, of highly conductive carbon blacks. Alternatively, the electrically conductive functional layer can be formed as a coating of intrinsic functional polymers. Typical functional polymers can be polythiophenes, polypyrroles, polyanilines, or polyethylene dioxythiophenes, among others.

The present invention provides a method for printing electrical and/or electronic structures which uses the advantages of the very high resolution of offset printing and at the same time transfers layers of very high and homogeneous thickness to the printing material. This is achieved by applying the structure of the electrical component to the printing material in one or more first printing units 11 by means of an adhesive. In a subsequent step, the printing material that has been imprinted with a design corresponding to the electrical structure is preferably brought into contact in one or more second printing units 12 with a transfer film (film 15) with a conductive coating. The conductive coating is transferred from the film 15 to the areas of the printing material that are imprinted with adhesive. The conductive coating can be, for instance, of a metallic type, or can consist of conductive carbon blacks or functional polymers. The coating process can be performed inline in printing units of an offset printing machine or in operating units, such as varnish modules, integrated into the offset printing machine.

### LIST OF REFERENCE NUMBERS

1 Impression cylinder
2 Press roller
3 Transfer gap
10 Printing machine
11 Printing unit
12 Printing unit
13 Printing unit
14 Arrow
15 Film
16 Drum, supply reel
17 Deflection roller
18 Drum, winding reel

1-24. (canceled)

25. A method for printing electrical structures on a printing material wherein the printing material to be printed is moved through a plurality of serially-arranged printing units of a printing machine, comprising the steps of:
applying an adhesive to an area of the printing material in a pattern corresponding to a predetermined electrical structure in at least one first printing unit;
feeding the printing material to at least one second printing unit; and
applying in the at least one second printing unit a conductive material to the area of the printing material to which adhesive was applied.

26. The method according to claim 25 wherein the at least one first printing unit is in at least one offset printing unit.

27. The method according to claim 25 wherein the at least one first printing unit is at least one letterpress printing unit.

28. The method according to wherein the conductive material is applied from a foil in the at least one second printing unit.

29. The method according to claim 28 further including the step of recoating the film with conductive material following application of the conductive material to the area of the printing material to which adhesive was applied.

30. The method according to claim 29 wherein one of a roll mill, a screen roller or a spraying device is used for recoating the film.

31. The method according to claim 25 wherein the printing material is fed to a cylinder in the at least one second printing unit which is used to apply the conductive material.

32. The method according to claim 31 further including the step of recoating the cylinder with conductive material following application of the conductive material to the area of the printing material to which adhesive was applied.

33. The method according to claim 25 further including the step of adjusting a thickness of the conducting material on the printing material to a predetermined thickness after application of the conductive material.

34. A film for use in printing electrical structures on a printing material, the film comprising a carrier film and an electrically conductive layer positioned on the carrier film, wherein the electrically conductive layer has a defined resistance.

35. The film according to claim 34 wherein an intermediate layer is positioned between the carrier film and the electrically conductive layer positioned on the carrier film.

36. The film according to claim 35 wherein the electrically conductive layer is a substantially metallic layer.

37. The film according to claim 36 wherein the metallic electrically conductive layer is vapor deposited on the intermediate layer by vapor deposition.

38. The film according to claim 36 wherein the metallic electrically conductive layer is coated on to the intermediate layer.

39. The film according to claim 34 wherein the electrically conductive layer comprises a highly conductive carbon black coating.

40. The film according to claim 34 wherein the electrically conductive layer comprises an intrinsic functional polymer coating.

41. The film according to claim 40 wherein the intrinsic functional polymer coating is made of one of the group consisting of polythiophenes, polypyrroles, polyanilines or polyethylene dioxythiophenes.

42. The film according to claim 34 wherein the carrier film comprises a low-energy carrier film with a surface energy of less than 35 mNm.

43. The film according to claim 35 wherein the intermediate layer comprises a low-energy separation layer with a surface energy of less than 35 mNm.

44. The film according to claim 35 wherein the intermediate layer comprises a wax.

45. The film according to claim 35 wherein the intermediate layer is formed from a silicone.

46. The film according to claim 34 wherein the electrically conductive layer is laminated to the carrier film.

47. The film according to claim 34 wherein the electrically conductive layer is directly adhered to the carrier film.

48. The film according to claim 10 wherein the electrically conductive functional layer is directly connected to the carrier film by electrostatic charge forces.
